(19) United States
(12) Patent Application Publication
(10) Pub. No.: US 2022/0375898 A1
(43) Pub. Date: Nov. 24, 2022

(54) PROGRAMMABLE CAPACITANCE IN THREE-DIMENSIONAL STACKED DIE ARCHITECTURE

(71) Applicant: Intel Corporation, Santa Clara, CA (US)

(72) Inventors: Vishram Shriram Pandit, Bangalore (IN); Narayanan Natarajan, Bengaluru (IN); Jayanth M. Kalyan, Bangalore (IN); Khondker Z. Ahmed, Hillsboro, OR (US); Jonathan P. Douglas, Cave Creek, AZ (US); Gururaj K. Shamanna, Austin, TX (US); Chin Lee Kuan, Bentong (MY)

(73) Assignee: Intel Corporation, Santa Clara, CA (US)

(21) Appl. No.: 17/323,094

(22) Filed: May 18, 2021

(51) Int. Cl. H01L 25/065; H01L 23/522; H01L 23/528; H01L 23/48

(52) U.S. Cl. CPC H01L 25/0657; H01L 23/5223; H01L 23/5226; H01L 23/5286; H01L 23/481; H01L 2225/06513; H01L 2225/06517

(57) ABSTRACT

An Integrated Circuit (IC) package is provided, comprising a first IC die having a first capacitor and a logic circuit, and a second IC die having a second capacitor. The first IC die and the second IC die may be stacked within the IC package one on top of another and electrically coupled with die-to-die interconnects. The logic circuit is electrically coupled in a power delivery network to the first capacitor and the second capacitor. The first IC die and the second IC die include respective back-end-of-line portions in which the first capacitor and the second capacitor, which may comprise metal-insulator-metal capacitors in some embodiments are situated. In some embodiments, the second capacitor is situated in a shadow of the logic circuit. In various embodiments, the first IC die and the second IC die comprise any suitable pair in a plurality of stacked IC dies within an IC package.

### TECHNICAL FIELD

The present disclosure relates to techniques, methods, and apparatus directed to programmable capacitance in three-dimensional stacked die architecture.

### BACKGROUND

Over the past few decades, shrinking of feature structures in integrated circuits (ICs) has been a driving force in the semiconductor industry, allowing for increased density of functional units on a limited base of semiconductor wafers. Passive components such as capacitors are also being integrated into metal layers in the dies in the form of Metal-Insulator-Silicon (MiS) and Metal-Insulator-Metal (MiM) capacitors, for example. In addition, multiple dies are being packaged together into a single package in a three-dimensional (3D) stacked configuration for increased performance with a more compact form factor that supports higher circuit densities.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a schematic cross-sectional view of an example IC package with programmable capacitance in 3D stacked die architecture, according to some embodiments of the present disclosure.

FIG. 1B is a schematic cross-sectional illustration of an example detail of the IC package, according to some embodiments of the present disclosure.

FIGS. 1C-1D are schematic views of example details of the IC package according to various embodiments of the present disclosure.

FIG. 2 is a chart showing an impedance profile of a power delivery network (PDN) with various arrangements of capacitors in the 3D stacked die architecture, according to the present disclosure.

FIG. 3 is a schematic block diagram of an example conductive pathway with programmable capacitance in the 3D stacked die architecture, according to some embodiments of the present disclosure.

FIG. 4 is a schematic circuit diagram of an example conductive pathway with programmable capacitance in the 3D stacked die architecture, according to some embodiments of the present disclosure.

FIG. 5 is a schematic block diagram of another example conductive pathway with programmable capacitance in the 3D stacked die architecture, according to some embodiments of the present disclosure.

FIGS. 6A and 6B are schematic block diagrams of example embodiments with programmable capacitance in the 3D stacked die architecture according to the present disclosure.

FIG. 7 is a schematic block diagram of yet another example conductive pathway with programmable capacitance in the 3D stacked die architecture, according to some embodiments of the present disclosure.

FIG. 8 is a chart showing impedance profile of another PDN with various arrangements of capacitors in the 3D stacked die architecture, according to the present disclosure.

FIG. 9 is a chart showing frequency response of yet another PDN with various arrangements of programmable capacitance in the 3D stacked die architecture according to embodiments of the present disclosure.

FIG. 10 is a simplified flow diagram illustrating an example method for configuring programmable capacitance in the 3D stacked die architecture according to embodiments of the present disclosure.

FIG. 11 is a cross-sectional view of a device package that may include one or more IC packages in accordance with any of the embodiments disclosed herein.

FIG. 12 is a cross-sectional side view of a device assembly that may include one or more IC packages in accordance with any of the embodiments disclosed herein.

FIG. 13 is a block diagram of an example computing device that may include one or more IC packages in accordance with any of the embodiments disclosed herein.

### DETAILED DESCRIPTION

Overview

For purposes of illustrating programmable capacitance in 3D stacked die architecture described herein, it is important to understand phenomena that may come into play during designing 3D stacked dies. The following foundational information may be viewed as a basis from which the present disclosure may be properly explained. Such information is offered for purposes of explanation only and, accordingly, should not be construed in any way to limit the broad scope of the present disclosure and its potential applications.

In a general sense, today's ICs are manufactured with increasingly higher performance, reduced costs, and increased miniaturization of components and devices. Many ICs such as processors, controllers, logic devices, memory devices and the like may be housed in a package including a substrate which supports a semiconductor die (also called IC die) and which further has internal electrical connections to provide interconnections (i.e., power, ground, and data) to the die. The package includes external electrical connections to enable the package to be electrically connected to, for example, a socket that may be adapted on a circuit board such as a motherboard or the like.

For many electronic technologies, the drive towards smaller devices with greater functionality runs up against challenges in PDN design. A PDN consists of all interconnections in a power supply pathway from voltage regulator modules to circuits on the die. For example, the PDN comprises printed circuit board (PCB) PDN, including voltage regulators (VRs) bulk decoupling capacitors, power and ground planes, any intervening vias, traces and relevant leads, multi-layer ceramic capacitors; package PDN, including power ground shapes, vias, traces, solder balls, wire-bonds, package capacitors, etc. of various components in the IC packages, and die PDN, comprising on-die capacitors and power grid for IC dies electrically coupled together for a particular functionality. To meet both supply voltage noise and timing budgets, the voltage noise on a PDN must be kept below some specified value, such as ±5% of the supply voltage or even lower across bandwidths ranging from 0 Hz (direct current (DC)) to 10 GHz or higher.

As used herein, the “PDN” comprises a conductive pathway for providing power, including reference voltage and ground, to one or more logic circuits on one or more IC dies; the PDN also provides a conductive return pathway for signals from such logic circuits. A “logic circuit” (also called “semiconductor intellectual property (IP) core” or “IP block” or “IP core” when referred to in a logical, as opposed to a physical, embodiment) as used herein may include any number and any combination of memory, multiplexer, logic gate, register, arithmetic logic unit, datapath, microprocessor core, digital signal processor, random control logic, network processor, peripheral, input/output interfaces, and other circuits with particularized functionality and input/output interfaces such that a combination of such logic circuits suitably electrically coupled to each other enables the IC die in which the logic circuits are situated to function according to its intended purposes. Input/output interfaces can comprise registers for memory (e.g., double data rate (DDR) DDRx, low power DDR (LPDDR) LPDDRx), peripheral component interconnect express (PCIE) PCIEx, universal serial bus (USB) USBx, serial advanced technology attachment (SATA) SATAx, display, High-Definition Multimedia Interface (HDMI) HDMIx, phased lock loop (PLL), etc.

In another example challenge in semiconductor technologies, next-generation gaming devices may require additional hardware to accommodate an increasing number of processing and graphics functionalities associated with virtual reality. To accommodate this additional hardware without increasing the overall device size, previously discrete, surface-mounted components are integrated into the package substrate itself in the form of MiMs in Back-End-of-Line (BEOL) metallization layers of individual IC dies and/or package capacitors in the package substrate. In these configurations, the MiM capacitors of individual IC dies are not coupled with each other in a single PDN; in other words, a PDN may comprise MiM capacitors in one IC die and package capacitors in the package substrate, but not MiM capacitors in another IC die for reasons explained further below with regard to the design process of individual IC dies. However, thin and light dual display systems require smaller package dimensions that cannot accommodate package capacitors. For these dual display systems, supply noise specifications cannot be mitigated with only BEOL layer MiM capacitors.

Some semiconductor packages include a mixed stack of active ICs (also called “devices” or “dies” or “IC dies”), for example, two active IC dies that are stacked one on top of the other to reduce form factor. In such stacked die architecture, for example, used in thin and light dual display systems, logic circuits such as processing (also called “core”), graphics, and input/output (I/O) in the top die have to meet supply noise requirements. Some stacked die packages use Land Side Capacitors (LSCs) in addition to the integrated MiM capacitors to meet the supply noise requirements. However, these LSCs can increase the size of the package overall thereby not meeting form factor restrictions. Some other packages use recess in motherboard (RIMB) or hole in motherboard (HIMB) for disposing LSCs underneath the package, because the capacitors are too large to fit in the space between the package substrate and the motherboard (also referred to as a PCB). However, such RIMB and HIMB require additional processing steps, such as cutting out a cavity for the capacitors etc. In addition, at least the first few layers of the PCB cannot be used for routing with the RIMB/HIMB cavity therein, resulting in higher IR-drop and higher loadlines. Besides, separate capacitors such as LSCs lead to higher bill of materials and consequently additional costs. Therefore, there is a need to address these problems in such 3D stacked die architecture using programmable capacitance as described herein.

In a typical design environment of a system comprising a PCB, a package, and one or more IC dies, the system PDN can have several sub-systems such as IC PDN, package PDN, and PCB PDN. Each such sub-system is configured separately, for example, because they work at different frequencies: the IC PDN may have the fastest operating frequencies and signal switching while the PCB PDN may have mostly slower signaling. Therefore, decoupling capacitors that are correspondingly suitable for these different frequencies are configured separately. In addition, in a typical design architecture of an IC die, the logic circuits of one die do not use passive components (e.g., capacitors) of another IC die. The IC design process involves a physical design stage, during which register-transfer level (RTL) behavioral model of the chip (used interchangeably herein with the term “IC die” or simply “die”) is transformed into actual geometric representations of its components, including capacitors, resistors, logic gates, and transistors. For example, during floorplanning, the RTL of the chip is assigned to physical regions on the chip, I/O pins are allocated appropriately, and logic circuits are positioned suitably. Such a design process involves a single IC die, without considering electronic components in any other IC die. In addition, each IC die typically performs independent power management of its internal components and sub-system PDNs.

In the design process of a multi-chip package, such as a stacked-die package, the individual IC dies are separately designed as described above, and the building up of the multi-chip modules typically involves coupling appropriate I/O pins in the separate IC dies so that logic circuits in one IC die can electrically communicate with logic circuits in another IC die. On-die MiS capacitors or MiM capacitors are placed near the logic circuits in the IC die; however, typically, they are not sufficient to mitigate noise when the logic circuits are operational. Any passives that need to be added to electrical pathways such as PDNs, for example, to lower supply voltage noise, are typically inserted off-chip (i.e., outside the IC dies) at the package level, for example, in the package substrate, or as LSCs outside the package as described above.

In contrast, in embodiments of the present disclosure, a logic circuit in one IC die is electrically coupled in a PDN to a capacitor in another IC die in the IC package. In one aspect of the present disclosure, an IC package includes a first IC die and a second IC die stacked within the IC package. The first IC die has a logic circuit and a first capacitor, and the second IC die has a second capacitor. The logic circuit on the first IC die is electrically coupled to the first capacitor and the second capacitor. In various embodiments, the stacked arrangement enables a short coupling path between the logic circuit and the second capacitor. As used herein, the term “stack” and “stacked” with regard to IC dies refers to an arrangement of IC dies one on top of another.

Note that capacitance from such integrated capacitors in the two separate IC dies is not the same as parasitic capacitance in a conductive pathway, for example, between a logic circuit in the first IC die and another logic circuit in the second IC die. Parasitic capacitance, or stray capacitance, is an unavoidable and unwanted capacitance that exists between conductive parts of an electronic circuit simply because of proximity to each other within an electric field. Such parasitic capacitance is uncontrolled and non-programmable. In contrast, in embodiments of the present disclosure, programmable capacitance refers to capacitance intentionally introduced in a conductive pathway as described herein. Further, such integrated on-chip capacitors in the two separate IC dies are not the same as discrete capacitors disposed off-chip, for example, LSCs external to the IC package.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices. The term “circuit” means one or more passive and/or active components that are arranged to cooperate with one another to provide a desired function. The terms “substantially,” “close,” “approximately,” “near,” and “about,” generally refer to being within +/−20% of a target value (e.g., within +/−5 or 10% of a target value) based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers. In addition, the term “dispose” as used herein refers to position, location, placement, and/or arrangement rather than to any particular method of formation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. When used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

In the drawings, a particular number and arrangement of structures and components are presented for illustrative purposes and any desired number or arrangement of such structures and components may be present in various embodiments. Further, the structures shown in the figures may take any suitable form or shape according to material properties, fabrication processes, and operating conditions.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

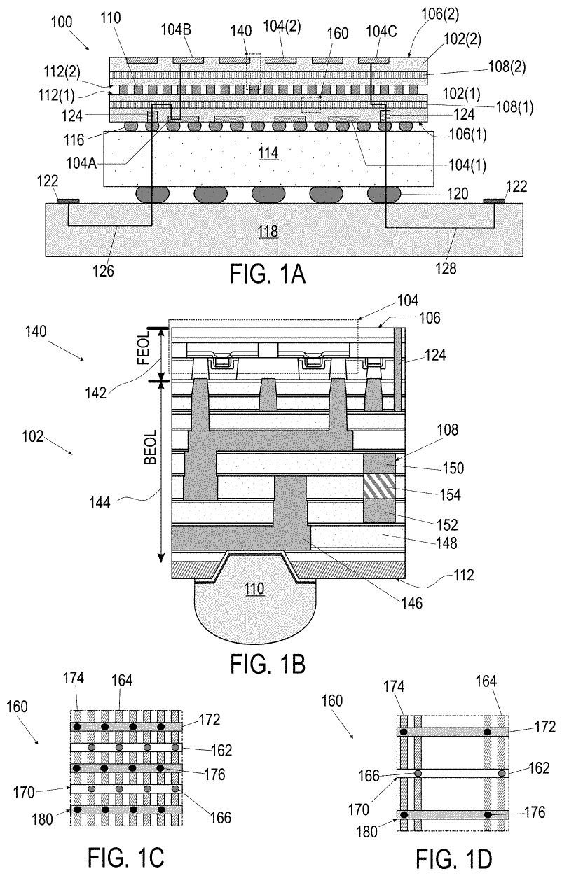

FIG. 1A is a schematic cross-sectional illustration of an IC package 100 with programmable capacitance according to some embodiments of the present disclosure. As shown, IC package 100 may include an IC die 102, for example a first IC die 102(1), having one or more logic circuits 104, for example 104(1). In a general sense, IC die 102 may be any suitable device, such as a processing die, a compute die, a memory die, a platform controller hub die, a power amplifier (PA), a switching die, a resonator, etc. In various embodiments, IC die 102 may have a backside 106 (e.g., 106(1)). IC die 102 may include one or more integrated capacitor 108 (e.g., 108(1)) situated therein. IC package 100 may include a second IC die 102(2) having one or more logic circuits 104(2), backside 106(2) and one or more integrated capacitor 108(2) situated therein.

IC die 102(1) may be coupled to IC die 102(2) by way of die-to-die (DTD) interconnects 110 (also called silicon-level interconnects). In some embodiments, DTD interconnects 110 are located over a frontside 112, for example frontside 112(1) of IC die 102(1) and frontside 112(2) of IC die 102(2). In other embodiments, DTD interconnects 110 may be located over backside 106, for example backside 106(1) of IC die 102(1) and backside 106(2) of IC die 102(2). In yet other embodiments, DTD interconnects 110 may be disposed over backside 106(1) of IC die 102(1) and frontside 112(2) of IC die 102(2) or vice versa. DTD interconnects 110 may comprise any suitable direct conductive electrical coupling between two different IC dies 102(1) and 102(2). For example, copper pillars, copper pillars with solder caps (C2), fine-pitch controlled collapse chip connection (C4) (with sub-100 μm pitch), wirebonds, indium bumps, indium-coated gold bumps, gold bumps, silicon interface bump (SIB), and other such microbump technology-based flip-chips are included among embodiments of DTD interconnects 110. In various embodiments, DTD interconnects 110 may have a pitch of 50 μm-10 μm.

IC die 102(1) may be coupled to a package substrate 114 by way of die-to-package substrate (DTPS) interconnects 116, for example, flip-chips or ball grid array (BGA). In various embodiments, DTPS interconnects 116 may have a pitch of around 180 μm. In some embodiments, DTPS interconnects 116 may have a pitch of 110 μm. Package substrate 114 may be coupled to a PCB 118 by way of package-to-PCB (PTP) interconnects 120, for example, ball grid arrays (BGAs), pin-grid arrays (PGAs) or land-grid arrays (LGAs).

Although FIG. 1A depicts only two IC dies 102(1) and 102(2), this is simply for ease of illustration, and any of IC packages 100 disclosed herein may include any desired number of additional components (or fewer components, as appropriate). For example, IC package 100 disclosed herein may include N number of IC dies 102(1), 102(2), . . . 102(N) stacked one on top of another, two or more such IC die 102 comprising logic circuit 104 and integrated capacitor 108, among other components. IC package 100 may include passive components (e.g., resistors, inductors, capacitors, or combinations thereof) disposed within or at either face of package substrate 114, or PCB 118 or in any other suitable location. For example, a contact pad 122 to couple to an external system may be disposed over a face of PCB 118.

In various embodiments, IC dies 102(1) and 102(2) are stacked one on top of another and interconnected vertically using through-silicon vias (TSVs) 124. In various embodiments, TSV 124 may have a diameter of 12 μm and be disposed with a 180 μm pitch. In some embodiments (e.g., as shown), IC die 102(1) and 102(2) may be coupled face to face with DTD interconnects 110. In such embodiments, lower IC die 102(1) has TSVs 124 that enable electrical coupling between frontside 112(1) and backside 106(1), where a redistribution layer may be disposed with pads on to which DTPS interconnects 116 may be attached to couple IC die 102(1) with package substrate 114.

In another embodiment, two or more IC dies may be placed one on top of the other, with their active areas facing downwards. In such embodiments, DTD interconnects may be disposed over backside 106(1) of lower IC die 102(1) and over frontside 112(2) of upper IC die 102(2). TSVs 124 that pass through lower IC die 102(1) electrically couple to DTD interconnects 110 on the top die through an appropriate redistribution layer on backside 106(1), and further to logic circuits 104(2) situated in upper IC die 102(2). DTPS interconnects 116 on second surface 112(1) of lower IC die 102(1) connect the die assembly to package substrate 114.

In other IC assemblies, IC package 100 (e.g., in accordance with any of the embodiments disclosed herein) may be coupled to another IC package, a package interposer, or any other suitable support that may take the place of PCB 118. In some such embodiments, package substrate 114 may function as an interposer in the IC package assembly having another package substrate. Further, although IC package 100 of FIG. 1A (and others of the accompanying drawings) includes IC die 102 coupled directly to package substrate 114, in any of the embodiments disclosed herein, an intermediate component may be disposed between IC die 102 and package substrate 114 (e.g., an interposer, a silicon bridge, an organic bridge, etc.).

The arrangement of components as shown in FIG. 1A can enable various conductive pathways such as pathway 126. Pathway 126 may comprise a PDN including conductive coupling between pad 122 on PCB 118, a particular one 104A of logic circuit 104(1) in IC die 102(1) and a particular one 104B of logic circuit 104(2) in IC die 102(2). In various embodiments, pathway 126 may conductively couple logic circuit 104A in IC die 102(1) with capacitor 108(1) in IC die 102(1) and capacitor 108(2) in IC die 102(2) by way of DTD interconnects 110 and other conductive elements, such as TSV 124. In some embodiments, capacitor 108(1) may comprise a high frequency capacitor situated at an input to logic circuit 104A, and capacitor 108(2) may be situated at an output of logic circuit 104A. In some embodiments, pad 122 may comprise a conductive coupling to another IC package, for example, housing a power management IC (PMIC). In some embodiments, logic circuit 104A may comprise a digital linear voltage regulator (DLVR) and logic circuit 104B may comprise a processor core circuit.

In various embodiments, pathway 126 may be configured during a design phase of IC package 100, for example, during a design phase of IC die 102(1) and IC die 102(2) before the respective dies are manufactured. Pathway 126 may be configured for a particular capacitance value resulting from a specific coupling of capacitors 108(1) and 108(2) in some embodiments. For example, connecting a portion of capacitors 108(1) and 108(2) in parallel may result in a cumulative capacitance value. In some other embodiments, pathway 126 may be configured for a suitable frequency response of the PDN as a result of coupling capacitors 108(1) and 108(2). In various embodiments, providing additional capacitance to logic circuit 104A in IC die 102(1) than can be provided by capacitor 108(1) thereon may be facilitated by coupling capacitor 108(2) in IC die 102(2) to capacitor 108(1) without resorting to LSCs or other external capacitors outside dies 102(1) and 102(2).

In another example pathway 128, logic circuit 104C in IC die 102(2) may be coupled to capacitor 108(2) in IC die 102(2) and capacitor 108(1) in IC die 102(1) by way of DTD interconnects 110 and other components. The example pathway may comprise a PDN electrically coupled to logic circuit 104C on top IC die 102(2) through bottom IC die 102(1). For example, pathway 128 may comprise a conductive pathway from pin 122 on PCB 118, through PTP interconnects 120, through package substrate 114, through DTPS interconnects 116, through TSV 124, metal traces comprising a metal grid in IC die 102(1), capacitor 108(1), metal traces comprising another metal grid in IC die 102(1), DTD interconnects 110, metal traces comprising a metal grid in IC die 102(2), capacitor 108(2), and logic circuit 104C along with conductive traces and vias electrically coupling these elements. In various embodiments, a particular one of capacitor 108(1) may be situated in a shadow of corresponding logic circuit 104C in IC die 102(2) to which it is coupled. A “shadow” of a logic circuit as used herein refers to a region located underneath or above the logic circuit, with a size and bounding shape corresponding to the size and bounding shape of the logic circuit. For example, the shadow in a first die of a logic circuit in a second die may comprise an imaginary projection on the first die of an area occupied by the logic circuit on the second die. In some embodiments in which logic circuits 104(1) in die 102(1) operate at low frequency that do not need high capacitance, capacitors 108(1) located in the shadow may be used by logic circuits 104(2) in die 102(2).

With such 3D-sharing of capacitors situated in two separate IC dies 102(1) and 102(2) stacked one above the other, for example, sharing top die capacitor 108(2) and bottom die capacitor 108(1), improved performance can be achieved for IC package 100. Various values of capacitance can be obtained by coupling capacitors 108(1) and 108(2) appropriately in a PDN. For example, a portion of capacitor 108(1) may be combined with another portion of capacitor 108(2) to obtain a desired value of total capacitance in the PDN. In another example, a portion of capacitor 108(1) may be combined with another portion of capacitor 108(2) to obtain a desired frequency response of the PDN. Thus, appropriate capacitor coupling can enable a programmable (e.g., tunable) solution for meeting capacitance value and/or frequency response specifications that avoids use of external LSCs, thereby simplifying package assembly processes. Further, RIMB or HIMB can also be avoided, simplifying manufacturing of PCBS. Coupling integrated capacitors as described herein can also lower bill of materials (BOM) costs for external package capacitors, RIMB and assembly processes while also maintaining or reducing package footprint to comply with thin and light system targets. Because of reduced IR drops from using integrated capacitors, improved battery size and/or battery capacity may also be achieved.

In a general sense, 3D stacking of dies 102 provides spatial access to integrated capacitors 108 (e.g., 108(1)) on one IC die (e.g., 102(1)) from logic circuit 104 (e.g., logic circuit 104(2)) on another IC die (e.g., 102(2)). Further, in the 3D stacked configuration, an upper die (e.g., IC die 102(2)) may comprise high performance logic circuits 104 such as a processing core, graphics or high-speed 10 ports. Logic circuits 104 may require supply decoupling to meet power supply droop performance/noise targets (e.g., such decoupling may be enabled by integrated capacitors 108(2) on upper IC die 102(2)). On the other hand, a lower die (e.g., IC die 102(1)) may comprise lower frequency and lower performance logic circuits 104 that do not need high decoupling capacitance and can function suitably with a lower portion of capacitors 108 disposed therein. Such functional partitioning of logic circuits 104 between different stacked dies along with spatial accessibility of integrated capacitors 108 through DTD interconnects 110 may be exploited in various embodiments. For example, capacitance available in IC die 102(1) may augment capacitance for logic circuits 104(2) situated in IC dies 102(2). Such sharing can enable a suitable PDN solution for high-performance logic circuits 104(2) to meet its targets such as supply voltage noise targets without help from structures such as LSCs or other external decoupling capacitance options which typically affect form factor and/or add cost. With the shared capacitance across a plurality of IC dies 102 (e.g., 102(1) and 102(2)), different capacitance values and frequency response of the PDN comprising capacitors 108 may be enabled to support various logic circuits 104 situated in different IC dies 102.

FIG. 1B illustrates a portion 140 of a cross-section of IC die 102 (e.g., 102(2)) in greater detail. IC die 102 may include a front-end-of-line portion (FEOL) 142 and a BEOL portion 144. FEOL 142 comprises isolated transistors, diodes, and other active electronic components of logic circuit 104 disposed over a suitable substrate. In general, the suitable substrate may comprise a semiconductor substrate composed of semiconductor materials including, for example, N-type or P-type materials. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. Although a few examples of materials from which the substrate may be formed are described here, any material that may serve as a foundation upon which a semiconductor device may be built falls within the spirit and scope of the present disclosure.

BEOL 144 may include various layers of conductive metal traces 146 comprising a metallization stack and interlayer dielectric (ILD) 148 comprising ILD layers. Other materials or/and layers, not specifically shown in FIG. 1B may also be provided as may be known to those skilled in the art. Electrical signals, such as power and/or I/O signals, may be routed to and/or from logic circuit elements (e.g., the transistors) of FEOL 142 through one or more conductive interconnect layers situated in BEOL 144 including metal traces 146, which may comprise one or more power grids, signal grids, and/or ground grids. A “power grid” is an arrangement of conductive lines, planes and vias, that is used to provide power to electronic elements in IC die 102. A “signal grid” is an arrangement of conductive lines, planes and vias that is used to provide signals (e.g., data) to logic circuit 104 in IC die 102. A “ground grid” is an arrangement of conductive lines, planes and vias that is used to provide ground connection to electronic elements in IC die 102.

In some embodiments, metal traces 146 may include lines and/or vias filled with an electrically conductive material such as aluminum. The lines comprising metal traces 146 may be arranged to route electrical signals in a direction of a plane that is substantially parallel with a surface of the semiconductor substrate upon which FEOL 142 is formed. For example, the lines may route electrical signals in a direction in and out of the page from the perspective of FIG. 1B. Vias may be arranged to route electrical signals in a direction of a plane that is substantially perpendicular to the surface of the semiconductor substrate upon which FEOL 142 is formed. In some embodiments, the vias may electrically couple lines of different metallization layers together.

ILD layers comprising ILD 148 may be deposited over and in between metal traces 146 of the metallization stack. The ILD layers may be formed using dielectric materials known for their applicability in IC structures, such as low-k dielectric materials. Examples of dielectric materials for ILD 148 include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant. Note that ILD 148 may comprise a homogeneous material, or a heterogeneous layered composite comprising more than one layer of material, or a heterogeneous matrix comprising a mixture of materials in any suitable arrangement known in the art.

In various embodiments, TSV 124 may be disposed through FEOL 142 into portions of BEOL 144, providing a conductive pathway from backside 106 into IC die 102. In such embodiments, BEOL 144 further includes bonding sites for DTD interconnects 110 proximate to frontside 112. In other embodiments, DTD interconnects 110 may be disposed proximate to backside 106, with electrical coupling into BEOL 144 provided through appropriate TSV 124. In yet other embodiments, DTPS interconnects 116 may be disposed proximate to backside 106 and electrically coupled to BEOL 144 through TSV 124. In some embodiments, TSVs from backside 106 may not extend to frontside 112 but may terminate at an intermediate metal layer in BEOL 144. TSV 124 may be electrically coupled to other components in die 102, for example, to a power grid or a ground grid as appropriate, or to DTD interconnects 110. The electrical coupling may be achieved using suitable metal traces 146. In embodiments in which DTPS interconnects 116 are disposed proximate to backside 106, for example, a conductive pathway to logic circuit 104 disposed in die 102 from DTPS interconnects 116 may comprise TSV 124, a power grid in one or more of the metal layers in BEOL 144, and metal traces 146 using vias as appropriate between metal layers.

In various embodiments, capacitor 108 may be situated in BEOL 144. Capacitor 108 may comprise a first layer of metal 150, separated from a second layer of metal 152 by a layer of dielectric 154. In various embodiments, first layer of metal 150 may be situated in one metallization layer in BEOL 144 and second layer of metal 152 may be situated in an adjacent metallization layer in BEOL 144. For example, first layer of metal 150 may be situated in metal layer 1 and second layer of metal 152 may be situated in metal layer 2. In other embodiments, first layer of metal 150 may be situated in one metallization layer in BEOL 144 and second layer of metal 152 may be situated in a non-adjacent metallization layer in BEOL 144. For example, first layer of metal 150 may be situated in metal layer 1 and second layer of metal 152 may be situated in metal layer 4. In some embodiments, dielectric 154 may comprise the same material as adjacent ILD 148; in other embodiments, dielectric 154 may comprise a different material from adjacent ILD 148.

In some embodiments, dielectric 154 may include a material such as tantalum and oxygen (e.g., in the form of tantalum oxide), zirconium and oxygen (e.g., in the form of zirconium oxide), hafnium and oxygen (e.g., in the form of hafnium oxide), or titanium and oxygen (e.g., in the form of titanium oxide), or silicon and oxygen (e.g., in the form of silicon oxide); or carbon along with silicon and oxygen (e.g., in the form of carbon doped silicon oxide); or tantalum and nitrogen (e.g., in the form of tantalum nitride); or a polymer such as benzocyclobutene (BCB); or inorganic amorphous materials such as phosphorus glass (PSG) and flurocarbon glass (FSG); or a combination of the above. In some embodiments, dielectric 154 may include one or more layers of metal oxides (e.g., titanium oxide), for example, with layers having different dielectric constants. In some such embodiments, thickness of dielectric 154 may be less than 100 nanometers. In some embodiments, dielectric 154 may include an ultra-high-k material (e.g., a material having a dielectric constant greater than 120). In some such embodiments, dielectric 154 may include barium, strontium, titanium, and oxygen (e.g., in the form of barium strontium titanate); or barium, titanium, and oxygen (e.g., in the form of barium titanate). Dielectric 154 may be fabricated using any suitable technique for integrated capacitors known in the art, such as physical vapor deposition (PVD), chemical vapor deposition (CVD), and spin-on deposition (SOD).

Capacitor 108 may be disposed anywhere within BEOL 144 within the scope of the present disclosure. For example, in some embodiments, capacitor 108 may be disposed closer to FEOL 142 (and backside 106) than to frontside 112); in other embodiments, capacitor 108 may be disposed closer to frontside 112 than to FEOL 142 (and backside 106); in yet other embodiments, capacitor 108 may be disposed mid-way between FEOL 142 (and backside 106) and frontside 112.

FIGS. 1C and 1D illustrate two different example embodiments of a configuration 160 of conductive metal traces in BEOL 144 in IC die 102, for example, IC die 102(2). The figures are not cross-sections, rather they may be considered akin to a top view. In the example embodiment shown in FIG. 1C, power lines 162 may be disposed above capacitor 108 and power lines 164 may be disposed beneath capacitor 108. Vias 166 connect power lines 162 and 164 suitably to capacitor 108. For example, power lines 162 may be connected to first layer of metal 150 and power lines 164 may be connected to second layer of metal 152 of capacitor 108 with vias 166. Power lines 162 and 164 may form a power grid 170. Ground lines 172 may be disposed above capacitor 108 and ground lines 174 may be disposed below capacitor 108. Vias 176 connect ground lines 172 and 174 suitably to capacitor 108. For example, ground lines 172 may be connected to first layer of metal 150 and ground lines 174 may be connected to second layer of metal 152 of capacitor 108 with vias 176. Ground lines 172 and 174 may form a ground grid 180. Spacing for power grid 170, ground grid 180 and vias 166 and 176 may be determined according to process rules and maximized by utilizing substantially all available space.

In the example embodiment shown in FIG. 1D, power lines 162 and 164 may be situated in a sparse arrangement to form a non-uniform power grid 170. Likewise, ground lines 172 and 174 may be situated in a sparse arrangement to form a non-uniform ground grid 180. Vias 166 and 176 in such a sparse arrangement provide a spatially non-uniform coupling to capacitor 108. Although sheet resistance may be the same for arrangements shown in FIG. 1C and FIG. 1D (e.g., fixed by processing parameters to around 50 Ω/μm²), the effective resistance of the entire metal grid together with capacitor 108 may be different for both, with effective resistance of the uniform arrangement of FIG. 1C being lower than the effective resistance of the non-uniform arrangement of FIG. 1D. This effective resistance may impact the overall frequency response of the PDN comprising capacitor 108. In various embodiments, a spacing of conductive vias 166 and 176 may also be based on the frequency response of the PDN comprising the capacitor 108. For example, a first capacitor configuration with uniform via spacing as depicted in FIG. 1C may have capacitance of 50 nF, effective resistance of 4 mΩ, and 3 dB frequency point of 500 MHz; a second capacitor configuration with non-uniform via spacing as depicted in FIG. 1D may have capacitance of 50 nF, effective resistance of 40 mΩ, and 3 dB frequency point of 50 MHz.

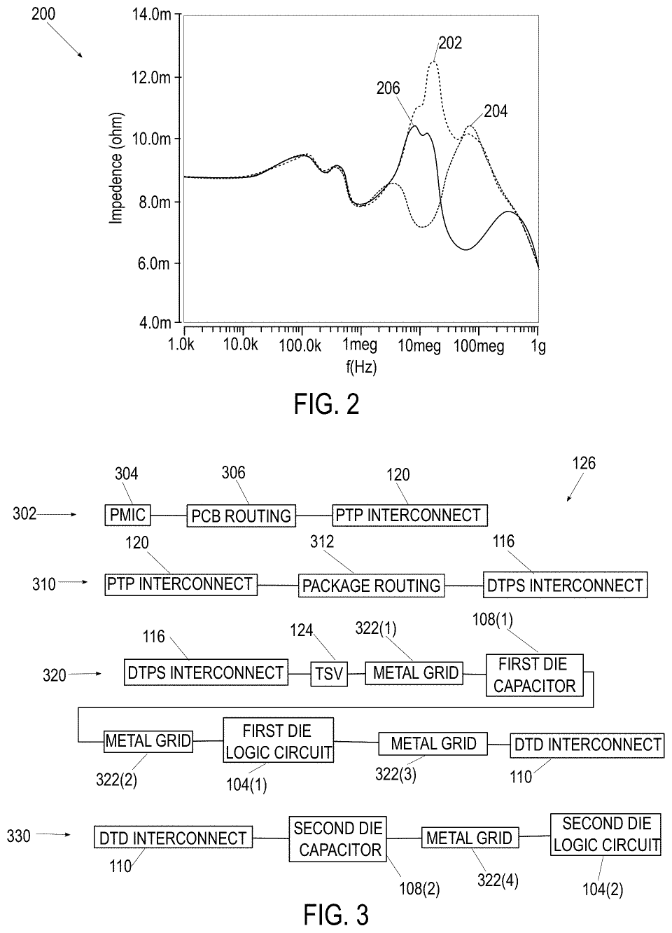

FIG. 2 is a graph 200 showing self-impedance profiles (or frequency domain response) of a PDN with three configurations of IC package 100 according to various embodiments. In the example shown, self-impedance of the PDN near logic circuits 104(2) in IC die 102(2) is plotted with self-impedance in ohms plotted on the Y-axis against frequency in Hertz along the X-axis. Self-impedance is a measure of compliance with supply voltage noise targets: higher the self-impedance, lower the compliance. In many applications, the supply voltage noise target can range from 5 mV to 50 mV depending on the specific combination of logic circuits used in the IC die. Profile 202 represents a configuration with no capacitor sharing across IC dies 102. In other words, IC die 102(2) uses capacitors 108(2) therein, and is not coupled to capacitors 108(1) in IC die 102(1). The self-impedance of such a configuration does not meet the supply voltage noise targets in many applications.

Profile 204 represents a configuration with LSCs along with capacitors 108(2) within the same IC die 102(2) as the logic circuit 104(2). In other words, off-chip (external) LSCs are located underneath package 114 to reduce the maximum impedance. As can be seen from 204, the self-impedance is lowered when LSCs are used, allowing supply noise targets to be met.

Profile 206 represents a configuration according to embodiments of the present disclosure, with capacitor sharing across multiple IC dies 102. Profile 206 represents the self-impedance of the PDN for logic circuit 104(2) in IC die 102(2). Accordingly, logic circuit 104(2) in IC die 102(2) may augment capacitance from on-chip capacitor 108(2) in IC die 102(2) with on-chip capacitors 108(1) in IC die 102(1). As can be seen from profile 206, the self-impedance of such a configuration is similar to the self-impedance of a configuration using off-chip LSCs as represented by profile 204. Further, the highest value of self-impedance in 206 is obtained at lower frequencies than in 204, which may be desirable in some applications.

FIG. 3 is a simplified block diagram illustrating example conductive pathway 126 in IC package 100 according to some embodiments. In one example embodiment, conductive pathway 126 may represent a PDN through several discrete components, such as logic circuit 104(2) in IC die 102(2) electrically coupled to logic circuit 104(1) (e.g., DLVR) in IC die 102(1) located beneath IC die 102(2). Conductive pathway 302 represents a PDN through PCB 118. Conductive pathway 302 comprises a PMIC 304, PCB routing 306, for example, including conductive traces, vias, pads and passives, including capacitors, and PTP interconnects 120. Conductive pathway 310 represents a PDN through package substrate 114, and includes PTP interconnects 120, package routing 312, including conductive traces, vias, pads and passives, and DTPS interconnects 116. Conductive pathway 320 represents a PDN through a first IC die 102(1), and comprises DTPS interconnects 116, one or more TSV 124, a first metal grid 322(1) (e.g., comprising power grid 170 or ground grid 180 or a signal grid), first capacitor 108(1), a second metal grid 322(2) (e.g., input signal grid comprising input signals to logic circuit 104(1)), first logic circuit 104(1) (e.g., 104A) situated in IC die 102(1), a third metal grid 322(3) (e.g., output signal grid comprising output signals from logic circuit 104(1)) and DTD interconnects 110. Some embodiments may have more or fewer number of metal grid 322 than shown in the figure. Conductive pathway 330 represents a PDN through a second IC die 102(2), and comprises DTD interconnects 110, second capacitor 108(2), a fourth metal grid 322(4), and second logic circuit 104(2). In various embodiments, any of metal grid 322 (e.g., 322(1), 322(2), 322(3) and/or 322(4)) may comprise one or more layers of conductive traces that serve to couple logic circuit 104 (e.g., 104(1) and/or 104(2)) and capacitor 108 (e.g., 108(1) and/or 108((2)) to power, ground, and/or signal lines.

In many embodiments, conductive pathway 126 may comprise a suitable combination of PDNs 302, 310, 320 and 330. It is to be understood that the PDNs illustrated in the figure include forward paths and return paths (i.e., power and ground connections) between the components shown. For example, in an integrated DLVR power delivery configuration, different DLVR logic circuits 104(1) in IC die 102(1) may be connected to different logic circuits 104(2) in IC die 102(2) and the inputs thereto may be consolidated. In some cases, the output of DLVR circuits may be coupled to PDNs of different logic circuits 104(2) in IC die 102(2) by way of capacitor 108(2). To reduce input droops in voltage, the inputs to the VR circuits may be connected to capacitor 108(1) in IC die 102(1). In various embodiments, coupling capacitors 108 across two or more dies, for example, capacitors 108(1) and 108(2) to the PDNs appropriately can reduce input voltage droop.

In some embodiments, as shown in the figure, first capacitor 108(1) in first IC die 102(1) may be connected at an input to logic circuit 104(1) (e.g., VR circuits) in first IC die 102(1). Second capacitor 108(2) in second IC die 102(2) may be electrically coupled to an output from logic circuit 104(1) in first IC die 102(1). Respective capacitance values of capacitors 108(1) and 108(2) may be configured to enhance an overall performance of conductive pathway 126 represented by the PDN network. Enhancement may include reducing voltage droop, improving frequency response, meeting supply noise targets, and reducing self-impedance, among other factors. In various embodiments, capacitances may be programmed (e.g., tuned) accordingly among capacitors 108(1) and 108(2) between input and output of logic circuit 104 (e.g., 104(1)).

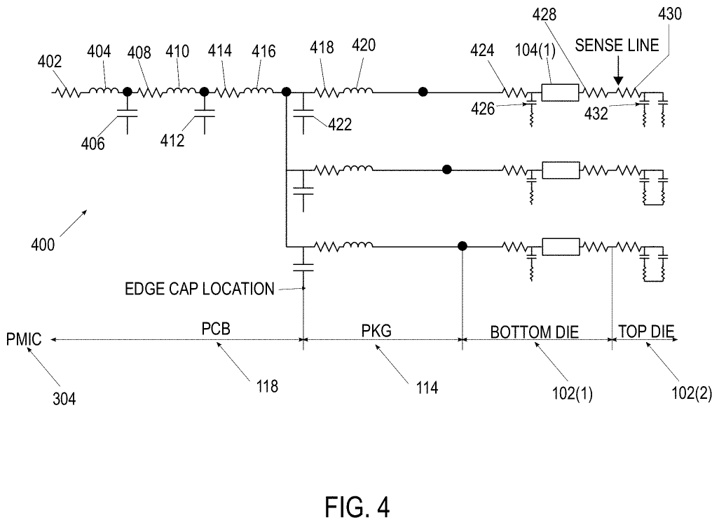

FIG. 4 is a schematic circuit diagram representing a circuit 400 according to various embodiments of the present disclosure. PMIC 304 provides a voltage source modeled using R_{pmic} 402 and L_{pmic} 404 as an equivalent circuit. C_{bulk} 406 represents bulk capacitor(s) for PMIC 304. PCB 118 may be modeled using parasitic resistor R_{brd} 408, parasitic inductor L_{brd} 410, parasitic capacitor C_{brd} 412, parasitic resistor R_{brd2} 414 and parasitic inductor L_{brd2} 416. Resistors 118 and inductors 420 represent coupling between different sections of IC package 100. Edge capacitors C_{edge} 422 may be disposed at a location where PCB 118 is coupled to package substrate 114. Note that three legs of package parasitic are modeled for coupling to three separate logic circuits 104 situated in IC die 102(2). In an example embodiment, the three separate logic circuits 104 may comprise a processor core in IC die 102(1), a ring, and another process core in IC die 102(2). PDN components in a first IC die 102(1) may be represented by Rᵢₙₚᵤₜ 424, capacitor 108(1) represented by capacitor 426 (including parasitic resistance and capacitance components), logic circuit 104(1) in IC die 102(1), and Rᵢₙₚᵤₜ 428. PDN components of second die 102(2) may be represented by grid resistance R_{grid} 430, and capacitor 108(2) represented by capacitor 432 (including parasitic resistance and capacitance components connected in parallel). In various embodiments, capacitor 108(1) may be coupled to logic circuit 104(1) at an input to logic circuit 104(1) as shown in circuit 400, according to the frequency response of the PDN comprising capacitor 108(1). In addition, because capacitor 108(1) is spatially close to logic circuit 104(1), additional parasitic, such as trace resistance, may be reduced.

In some embodiments, configurations coupling capacitor 108(1) and 108(2) in two separate IC dies 102(1) and 102(2) may enable better droop performance (e.g., reducing voltage droop) by around 17 mV between first and third droops with a guard band of 17 mV. In some other embodiments, for example, with a burst workload, configurations coupling capacitor 108(1) and 108(2) in two separate IC dies 102(1) and 102(2) may enable a difference between first and third droops of 45 mV and a guard band of 45 mV. In some embodiments, a capacitance density of 50 fF/μm² may represent a minimum value for capacitor 108(1) in IC die 102(1) for use by logic circuits 104(1) situated in IC die 102(1) to meet power noise specifications. Further, 50% of capacitor 108(1) may be utilized by logic circuits 104(2) situated in IC die 102(2), while the remaining 50% of capacitor 108(1) may be utilized by logic circuits 104(1) in IC die 102(1) that operate at a lower frequency, for example. Portions of capacitor 108(1) utilized by logic circuits 104(2) may be disposed spatially in a shadow of such logic circuits 104(2) in some embodiments. Logic circuits 104(1) disposed proximate to these portions of capacitor 108(1) may not need to use capacitor 108(1) to its fullest extent, or they may use the remaining available portion of capacitor 108(1), enabling sharing of capacitor 108(1) by logic circuits 104(1) and 104(2) situated in two separate dies. In some embodiments, logic circuits 104(1) in IC die 102(1) may be disposed proximate to a portion of capacitor 108(1) utilized by such logic circuits 104(1); likewise, logic circuits 104(2) in IC die 102(2) may be disposed such that another portion of capacitor 108(1) utilized by such logic circuits 104(2) is situated in a shadow of such logic circuits 104(2).

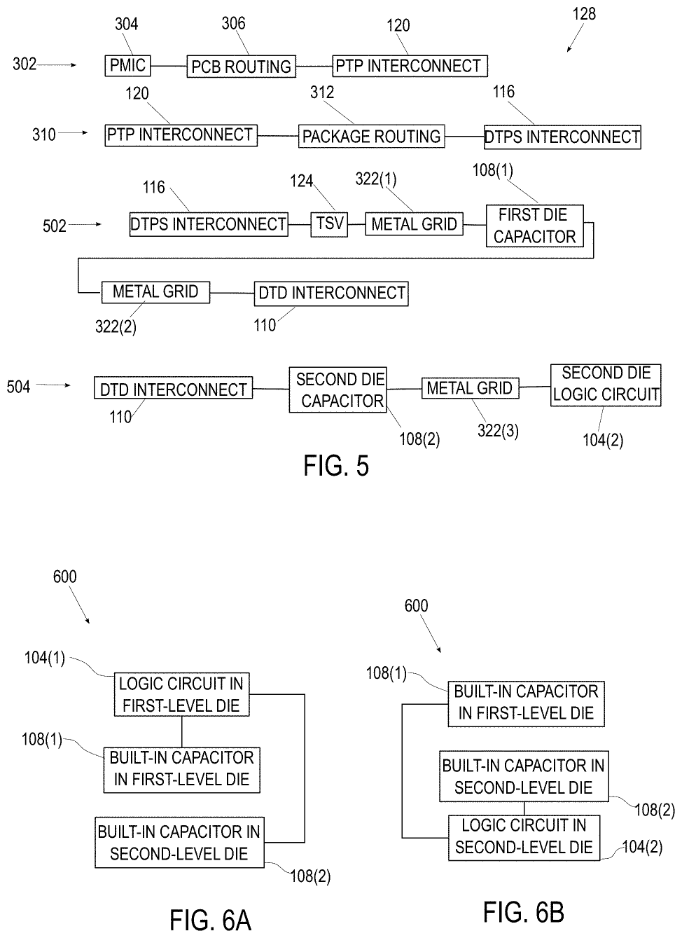

FIG. 5 is a simplified block diagram illustrating example conductive pathway 128 in IC package 100 according to some embodiments. In one example embodiment, conductive pathway 128 may represent a PDN through several discrete components. Conductive pathway 302 represents PDN through PCB 118. Conductive pathway 302 comprises PMIC 304, PCB routing 306, for example, including conductive traces, vias, pads and passives, including capacitors, and PTP interconnects 120. Conductive pathway 310 represents the PDN through package substrate 114, and includes PTP interconnects 120, package routing 312, including conductive traces, vias, pads and passives, and DTPS interconnects 116. Conductive pathway 502 represents a PDN through first IC die 102(1), and comprises DTPS interconnects 116, one or more TSV 124, a first metal grid 322(1), first capacitor 108(1), a second metal grid 322(2), and DTD interconnects 110. Conductive pathway 504 represents a PDN through second IC die 102(2), and comprises DTD interconnects 110, second capacitor 108(2), a third metal grid 322(3), and logic circuit 104(2) situated in second IC die 102(2).

In various embodiments, any of metal grid 322 (e.g., 322(1), 322(2) and/or 322(3)) may comprise one or more layers of conductive traces that serve to couple logic circuit 104 (e.g., 104(1) and/or 104(2)) and capacitor 108 (e.g., 108(1) and/or 108(2)) to power, ground, or signal lines. Some embodiments may have more or fewer number of metal grid 322 than shown in the figure. In many embodiments, conductive pathway 128 may comprise a suitable combination of PDNs 302, 310, 502 and 504. It is to be understood that the PDNs illustrated in the figure include forward paths and return paths (i.e., power and ground connections) between the components shown. In the example embodiment shown, first capacitor 108(1) and second capacitor 108(2) are disposed at an input to logic circuit 104(2).

In some embodiments, capacitor 108(1) may have a capacitance density of 100 fF/μm² with 50% utilization and capacitor 108(2) may have a capacitance density of 135 fF/μm² with 60% utilization. In some other embodiments, capacitor 108(1) may have a capacitance density of 50 fF/μm² with 50% utilization and capacitor 108(2) may have a capacitance density of 193 fF/μm² with 60% utilization. In some embodiments, additional capacitors (e.g., MiM capacitors) may be added to particular logic circuits 104 as needed in suitable IC die 102. In general, this capacitance density may vary with the particular MiM technology used to fabricate capacitor 108. In various embodiments, various capacitance values may be configured appropriately using capacitors 108 in more than one die, irrespective of the capacitance density or MiM technology in individual dies.

FIGS. 6A-6B are simplified block diagrams illustrating example embodiment 600 of IC package 100. A logic circuit 104(1) in a first IC die 102(1) on a first level (e.g., disposed proximate to package substrate 114) may be electrically coupled to a built-in (e.g., integrated) capacitor 108(1) in IC die 102(1) and to capacitor 108(2) in a second IC die 102(2) situated on a second level (e.g., atop first IC die 102(1)) as shown in FIG. 6A. A logic circuit 104(2) in second IC die 102(2) may be electrically coupled to capacitor 108(2) in IC die 102(2) and to capacitor 108(1) in first IC die 102(1) as shown in FIG. 6B.

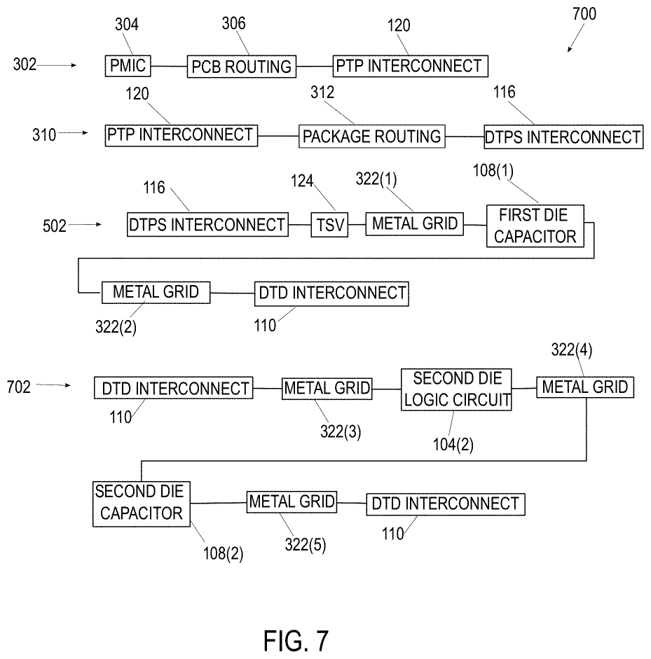

FIG. 7 is a simplified block diagram illustrating example conductive pathway 700 in IC package 100 according to some embodiments. In one example embodiment, conductive pathway 700 may represent a PDN through several discrete components. Conductive pathway 302 represents PDN through PCB 118. Conductive pathway 302 comprises PMIC 304, PCB routing 306, for example, including conductive traces, vias, pads and passives, including capacitors, and PTP interconnects 120. Conductive pathway 310 represents the PDN through package substrate 114, and includes PTP interconnects 120, package routing 312, including conductive traces, vias, pads and passives, and DTPS interconnects 116. Conductive pathway 502 represents a PDN through first IC die 102(1), and comprises DTPS interconnects 116, one or more TSV 124, a first metal grid 322(1), first capacitor 108(1), a second metal grid 322(2), and DTD interconnects 110. Conductive pathway 702 represents a PDN through second IC die 102(2), and comprises DTD interconnects 110, a third metal grid 322(4), logic circuit 104(2), a fourth metal grid 322(4), second die capacitor 108(2), a fifth metal grid 322(5), and DTD interconnects 110 situated in second IC die 102(2).

In various embodiments, any of metal grid 322 (e.g., 322(1), 322(2), 322(3), 322(4) and/or 322(5)) may comprise one or more layers of conductive traces that serve to couple logic circuit 104 (e.g., 104(1) and/or 104(2)) and capacitor 108 (e.g., 108(1) and/or 108(2)) to power, ground, or signal lines. In some embodiments, DTD interconnects 110 of PDN 702 may comprise coupling with IC die 102(1) beneath IC die 102(2); in other embodiments, DTD interconnects 110 of PDN 702 may coupling with another IC die 102 (not shown) above IC die 102(2) in a multi-die stacked arrangement. Some embodiments may have more or fewer number of metal grid 322 than shown in the figure. In many embodiments, conductive pathway 700 may comprise a suitable combination of PDNs 302, 310, 502 and 702. It is to be understood that the PDNs illustrated in the figure include forward paths and return paths (i.e., power and ground connections) between the components shown. In the example embodiment shown, first capacitor 108(1) is disposed at an input to logic circuit 104(2) and second capacitor 108(2) is disposed at an output from logic circuit 104(2).

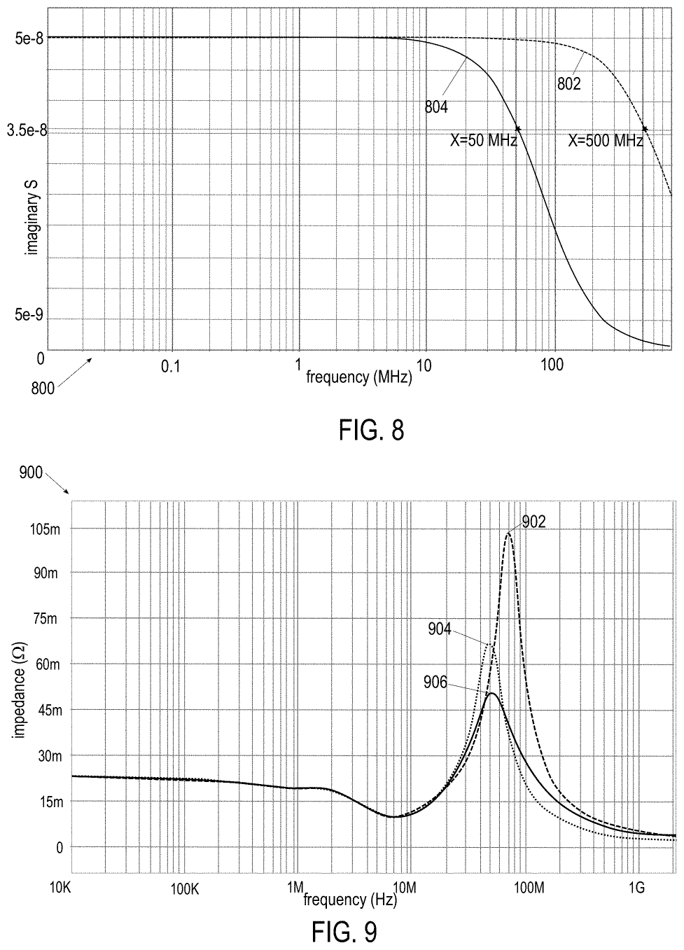

FIG. 8 is a graph 800 showing frequency response of capacitors comprising two different configurations of metal traces in IC package 100. In both configurations, the fabricating process of capacitors 108 is the same, and hence the sheet resistance is also the same for both. The configuration represented by plot 802 comprises a ‘uniform’ grid and via spacing of interconnection to capacitor 108, for example, as shown in FIG. 1C. The configuration represented by plot 804 comprises a ‘sparse’ grid and via spacing of interconnection to capacitor 108, for example, as shown in FIG. 1D. In an example simulation, the capacitance is 50 nF for both configurations. The effective resistance is 4 mΩ for the uniform grid and 40 mΩ for the sparse grid. The 3 dB frequency point for the uniform grid represented by plot 802 is 500 MHz, whereas for the sparse grid, represented by plot 804, the 3 dB frequency point is 50 MHz.

FIG. 9 is a graph 900 showing self-impedance profiles (or frequency domain response) of a PDN with three different configurations of capacitor sharing across IC dies. Plot 902 represents a configuration with no capacitance sharing across different IC dies 102, for example, 102(1) and 102(2). In a simulation used to generate plot 902, the capacitance of capacitor 108(1) in IC die 102(1) is 50 nF and effective resistance is 4 mΩ. The self-impedance peak, as shown by 902, is 103 mΩ at 68 MHz. Plot 904 represents a configuration with capacitance sharing using capacitor 108(1) and 108(2) situated in two separate IC dies 102(1) and 102(2), respectively. With capacitance and effective resistance of capacitor 108(1) and 108(2) being 50 nF, and 4 mΩ respectively according to the particular simulation, the self-impedance peak as indicated by 804 is 67 mΩ at 46 MHz. With damping in the PDN network, for example, by changing frequency response of the PDN using a different metal grid and via pattern (e.g., uniform grid as opposed to sparse grid), the PDN impedance can be lowered further. For capacitor 108(2), the effective resistance is same as 4 mΩ, but for capacitor 108(1), the effective resistance is 40 mΩ and corresponding self-impedance peak, as indicated by plot 906, is 50 mΩ at 50 MHz.

Example Methods

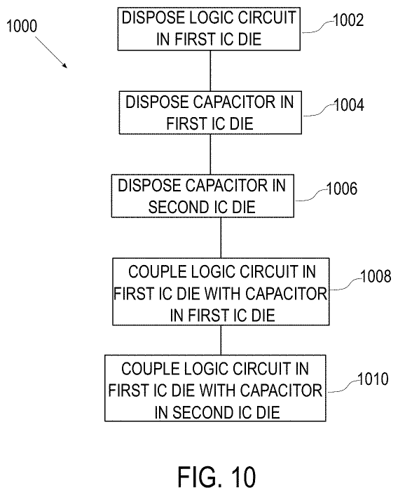

FIG. 10 is a simplified diagram illustrating an example method 1000 for programmable capacitance in three-dimensional stacked die architecture. At 1002, logic circuit 104(1) is situated in first IC die 102(1). At 904, capacitor 108(1) is situated in first IC die 102(1). At 1006, capacitor 108(2) is situated in second IC die 102(2). At 1008, logic circuit 104(1) in first IC die is electrically coupled in a PDN to capacitor 108(1) in first IC die 102(1). At 1010, logic circuit 104(1) in first IC die is electrically coupled in the PDN to capacitor 108(2) in second IC die 102(2). In some embodiments, the electrical coupling comprises disposing capacitor 108(1) at an input to logic circuit 104(1) and capacitor 108(2) at an output from logic circuit 104(1) in the PDN. In such embodiments, IC die 102(1) may be situated under IC die 102(2); IC die 102(1) may be coupled to package substrate 114 with DTPS interconnects 116. In some embodiments, the electrical coupling comprises disposing capacitor 108(1) and capacitor 108(2) at an input to logic circuit 104(1) in the PDN. In such embodiments, IC die 102(1) may be situated over IC die 102(2), which may be coupled to package substrate 114 with DTPS interconnects 116. In some embodiments, the electrical coupling comprises disposing capacitor 108(1) at an input to logic circuit 104(2) in the PDN, and capacitor 108(2) in IC die 102(2) at an output from logic circuit 104(2); in such embodiments, IC die 102(2) may be stacked over IC die 102(1), which may be coupled to package substrate 114 with DTPS interconnects 116. In various embodiments comprising many more IC dies stacked one over the other, IC die 102(1) and IC die 102(2) represents any suitable pair of IC dies in such a multi-die stack.

In various embodiments, programmable 3D-sharing of capacitance across multiple IC dies as described herein can provide various advantages, for example, form-factor benefits, capacitor cost savings, benefits in first droop, benefits in performance and frequency, programmability in allocation between input and output of integrated VR, flexibility in allocating between two different stacked IPs (i.e., logic circuits), addressing I/O noise specifications and broadband MiM decoupling. For meeting power noise specifications, typically off-chip LSCs in the package are used. The LSCs contribute to increasing the target package size and XYZ dimensions of the product. With package capacitors in RIMB or HIMB configuration, signal and power routing cannot be done in that specific area on the motherboard. As a result, the size of the PCB may increase reducing the available space for the battery. 3D sharing eliminates the need for package capacitors meeting the form-factor targets.

With 3D-sharing, expensive package capacitors can be avoided. It saves on capacitor cost, PCB manufacturing cost due to RIMB and assembly cost. Integrated MiM capacitors as described herein address high frequency and help in reducing the first voltage droop significantly. Without a bottom die MiM capacitors 108(1), the first voltage droop can be significantly higher in the absence of off-chip package capacitors (e.g., LSCs). 3D sharing of capacitance (e.g., 108(1) and 108(2)) as described herein can improve the first droop significantly. Lower first droop improves performance and frequency of the core. In addition, DLVR systems can operate at a lower input voltage, saving power. This power savings can be important in certain processors such as M segment processors. For integrated VRs, a MiM capacitor (e.g., 108(2)) in the top die (e.g., 102(2)) at the output of the VR, along with another MiM capacitor (e.g., 108(1)) in the bottom die (e.g., 102(1)) can provide high frequency capacitance at the input of the DLVR and close to the logic circuits. Overall, 3D sharing may give programmability in allocation of MiM capacitors between input and output as per any requirement.

Bottom die MiM capacitors 108(1) can be used for bottom IC die logic circuits as well as top die logic circuits. Low speed IPs (such as general purpose input output (GPIO), control signals) in the bottom IC die may not need large amount of MiM capacitance. So, the area can be used as capacitance targeted for top die IPs (i.e., logic circuits). Without capacitance sharing as described herein, high speed I/Os such as USB4, PCIE4, DDR5, LPDDR5 may need LSCs along-with MiM capacitors for mitigation of noise. 3D sharing eliminates need for the package capacitors such as LSCs for these I/Os. With top and bottom die MiM capacitors, overall broadband MiM solution can be determined by tuning their frequency response (e.g., providing frequency response programmability).

Although the operations of method 1000 are illustrated in FIG. 10 once each and in a particular order, the operations may be performed in any suitable order and repeated as desired. For example, one or more operations may be performed in parallel to manufacture multiple IC packages substantially simultaneously. In another example, the operations may be performed in a different order to reflect the structure of a particular IC package comprising programmable capacitance in 3D stacked die arrangement as described herein. In yet another example, the operations may be performed for multiple pairs of stacked IC dies in a multi-die stacked arrangement.

Furthermore, the operations illustrated in FIG. 10 may be combined or may include more details than described. Still further, method 1000 shown in FIG. 10 may further include other operations related to interconnecting other components described herein in a PDN. For example, method 1000 may include various designing operations, such as microarchitecture and system-level design, RTL design, physical design including layout, manufacturing, productization, and testing for incorporating IC packages as described herein in, or with, an IC component, a computing device, or any desired structure or device.

Example Devices and Components

The IC packages disclosed herein, e.g., any of the embodiments shown in FIGS. 1A-1D or any further embodiments described herein, may be included in any suitable electronic component. FIGS. 10-12 illustrate various examples of packages, assemblies, and devices that may be used with or include any of the IC packages with programmable capacitance in 3D stacked die architecture as disclosed herein.

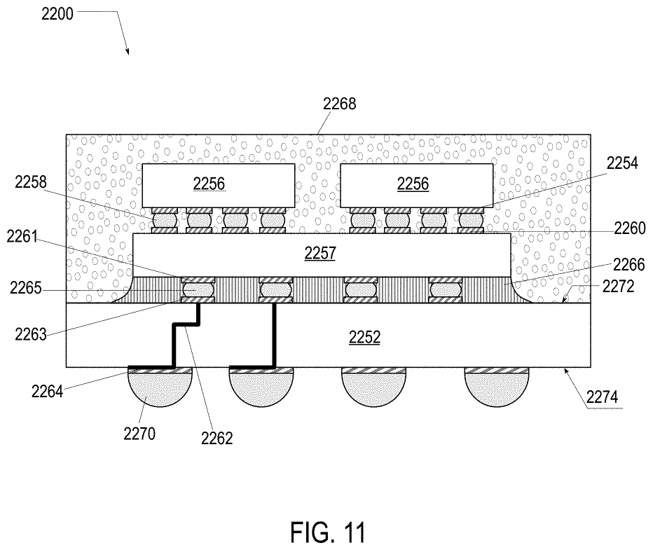

FIG. 11 is a cross-sectional side view of an example IC package 2200 that may include IC packages in accordance with any of the embodiments disclosed herein. In some embodiments, the IC package 2200 may be a system-in-package (SiP). As shown in FIG. 11, package support 2252 may be formed of an insulating material (e.g., a ceramic, a buildup film, an epoxy film having filler particles therein, etc.), and may have conductive pathways extending through the insulating material between a first face 2272 and a second face 2274, or between different locations on first face 2272, and/or between different locations on second face 2274. These conductive pathways may take the form of any of the interconnect structures comprising lines and/or vias, e.g., as discussed above with reference to FIG. 1A.

Package support 2252 may include conductive contacts 2263 that are coupled to conductive pathways 2262 through package support 2252, allowing circuitry within IC dies 2256 and/or interposer 2257 to electrically couple to various ones of conductive contacts 2264 (or to other devices included in package support 2252, not shown).

IC package 2200 may include interposer 2257 coupled to package support 2252 via conductive contacts 2261 of interposer 2257, first-level interconnects 2265, and conductive contacts 2263 of package support 2252. First-level interconnects 2265 illustrated in FIG. 11 are solder bumps, but any suitable first-level interconnects 2265 may be used, such as solder bumps, solder posts, or bond wires.

IC package 2200 may include one or more IC dies 2256 coupled to interposer 2257 via conductive contacts 2254 of IC dies 2256, first-level interconnects 2258, and conductive contacts 2260 of interposer 2257. Conductive contacts 2260 may be coupled to conductive pathways (not shown) through interposer 2257, allowing circuitry within IC dies 2256 to electrically couple to various ones of conductive contacts 2261 (or to other devices included in interposer 2257, not shown). First-level interconnects 2258 illustrated in FIG. 11 are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

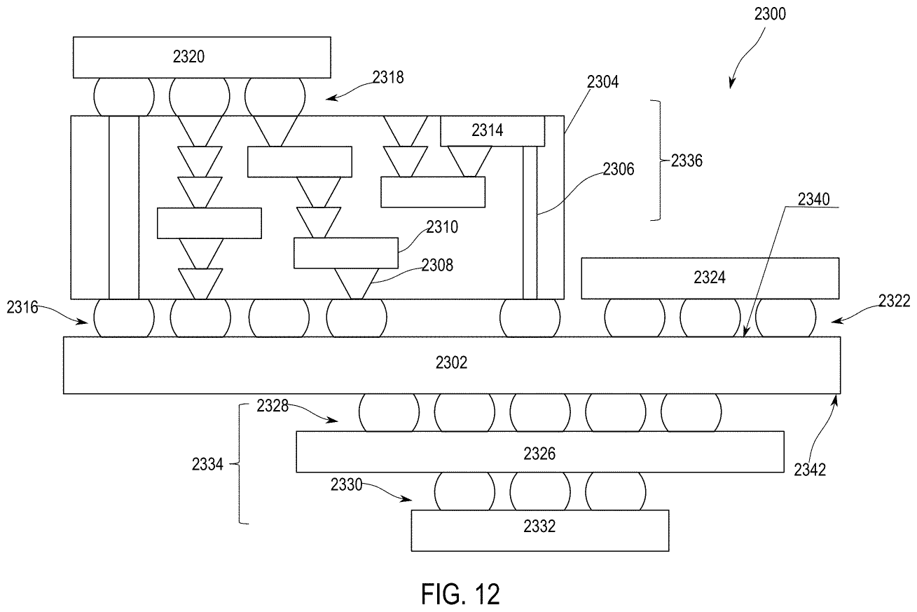

In some embodiments, underfill material 2266 may be disposed between package support 2252 and interposer 2257 around first-level interconnects 2265, and mold 2268 may be disposed around IC dies 2256 and interposer 2257 and in contact with package support 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in FIG. 11 are solder balls (e.g., for a BGA arrangement), but any suitable second-level interconnects 2270 may be used (e.g., pins in a PGA arrangement or lands in a LGA arrangement). Second-level interconnects 2270 may be used to couple IC package 2200 to another component, such as a circuit board (e.g., a motherboard), an interposer, or another IC package, as known in the art and as discussed below with reference to FIG. 12.

In various embodiments, any of IC dies 2256 may include IC dies 102 as described herein. In embodiments in which IC package 2200 includes multiple IC dies 2256, IC package 2200 may be referred to as a multi-chip package (MCP). IC dies 2256 may include circuitry to perform any desired functionality. For example, one or more of IC dies 2256 may be logic dies (e.g., silicon-based dies), one or more of IC dies 2256 may be memory dies (e.g., high bandwidth memory), etc. In some embodiments, at least some of IC dies 2256 may not include programmable capacitance across IC dies as described herein. In some embodiments, IC dies 2256 may comprise stacked IC dies in any suitable arrangement.

Although IC package 2200 illustrated in FIG. 11 is a flip-chip package, other package architectures may be used. For example, IC package 2200 may be a BGA package, such as an embedded wafer-level BGA (eWLB) package. In another example, IC package 2200 may be a wafer-level chip scale package (WLCSP) or a panel fan-out (FO) package. Although two IC dies 2256 are illustrated in IC package 2200, IC package 2200 may include any desired number of IC dies 2256. IC package 2200 may include additional passive components, such as surface-mount resistors, capacitors, and inductors disposed over first face 2272 or second face 2274 of package support 2252, or on either face of interposer 2257. More generally, IC package 2200 may include any other active or passive components known in the art.

In some embodiments, no interposer 2257 may be included in IC package 2200; instead, IC dies 2256 may be coupled directly to conductive contacts 2263 at first face 2272 by first-level interconnects 2265.

FIG. 12 is a cross-sectional side view of an IC device assembly 2300 that may include components having one or more IC package 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more IC package 100 with programmable capacitance in 3D stacked die arrangement in accordance with any of the embodiments disclosed herein; e.g., any of the IC packages discussed below with reference to IC device assembly 2300 may take the form of any of the embodiments of IC package 2200 discussed above with reference to FIG. 11.

In some embodiments, circuit board 2302 may be a PCB including multiple metal layers separated from one another by layers of insulating material and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package support.

FIG. 12 illustrates that, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 11. In some embodiments, IC package 2320 may include electrically intercoupled programmable capacitance as described herein.

Although a single IC package 2320 is shown in FIG. 12, multiple IC packages may be coupled to interposer 2304; indeed, additional interposers may be coupled to interposer 2304. Interposer 2304 may provide an intervening package support used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in FIG. 12, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304, for example, as shown in FIGS. 1-3.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

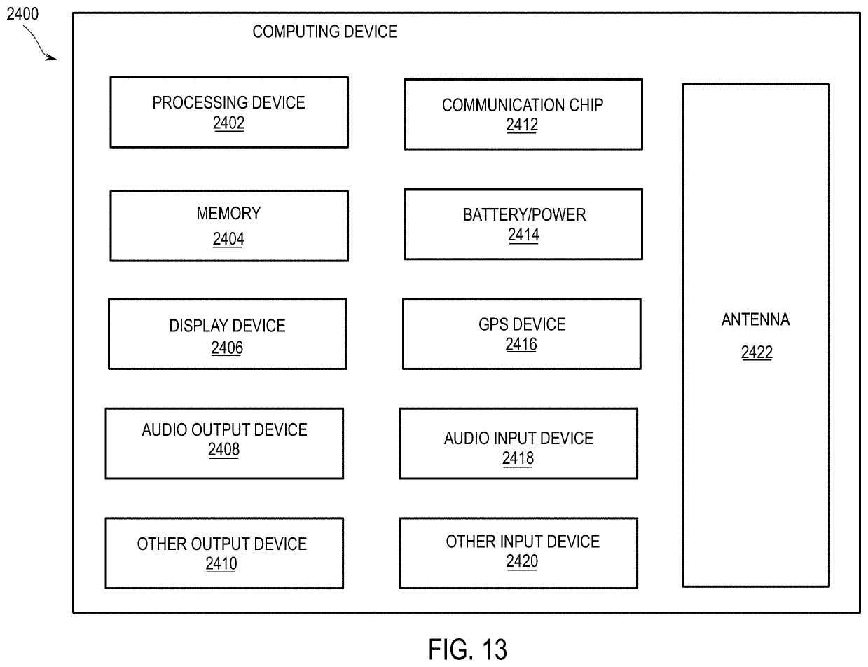

FIG. 13 is a block diagram of an example computing device 2400 that may include one or more components having one or more IC packages in accordance with any of the embodiments disclosed herein. For example, any suitable ones of the components of computing device 2400 may include an IC package 100 (e.g., IC package 100 as shown in FIGS. 1A-1D) in accordance with any of the embodiments disclosed herein. In another example, any one or more of the components of computing device 2400 may include any embodiments of IC package 2200 (e.g., as shown in FIG. 11). In yet another example, any one or more of the components of computing device 2400 may include an IC device assembly 2300 (e.g., as shown in FIG. 12).

A number of components are illustrated in FIG. 13 as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single system-on-a-chip (SoC) die.

Additionally, in various embodiments, computing device 2400 may not include one or more of the components illustrated in FIG. 13, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-M RAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile Internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

The following paragraphs provide various examples of the embodiments disclosed herein.

Example 1 provides an IC package (e.g., 100 in FIG. 1A) including a first IC die (e.g., 102(1)) having a first capacitor (e.g., 108(1)) and a logic circuit (e.g., 104(1)), and a second IC die (e.g., 102(2)) having a second capacitor (e.g., 108(2)). The first IC die and the second IC die are stacked within the IC package, and the logic circuit is electrically coupled to the first capacitor and the second capacitor.

Example 2 provides the IC package according to example 1, where the first capacitor is at an input to the logic circuit and the second capacitor is at an output from the logic circuit (e.g., as shown in FIG. 3).

Example 3 provides the IC package according to example 1, where the first capacitor and the second capacitor are at an input to the logic circuit (e.g., as shown in FIG. 5).

Example 4 provides the IC package according to example 3, where the first IC die is over the second IC die, and the second capacitor is situated in a shadow of the logic circuit.

Example 5 provides the IC package according to any of examples 1 to 4, where the first IC die and the second IC die include respective BEOL portions (e.g., 144 in FIG. 1B), where the first capacitor and the second capacitor comprise MiM capacitors in the respective BEOL portions.

Example 6 provides the IC package according to any of examples 1 to 5, where the second IC die is electrically coupled to the first IC die with DTD interconnects (e.g., 112).

Example 7 provides the IC package according to any of examples 1 to 6, where the first IC die and the second IC die comprise respective backsides and opposing frontsides, the respective BEOL portions are between the respective backsides and frontsides (e.g., as shown in FIG. 1B).

Example 8 provides the IC package according to any of examples 1 to 7, where the DTD interconnects are over the respective frontsides of the IC dies (e.g., as shown in FIG. 1B).

Example 9 provides the IC package according to any of examples 1 to 7, where the DTD interconnects are over the respective backsides of the IC dies.

Example 10 provides the IC package according to any of examples 1 to 7, where the DTD interconnects are over the backside of the first IC die and the frontside of the second IC die.

Example 11 provides the IC package according to any of examples 1 to 7, where the DTD interconnects are over the frontside of the first IC die and the backside of the second IC die.

Example 12 provides the IC package according to any of examples 1 to 11, where the first capacitor is located proximate to the frontside of the first IC die and the second capacitor is located proximate to the backside of the second IC die.

Example 13 provides the IC package according to any of examples 1 to 11, where the first capacitor is located proximate to the backside of the first IC die and the second capacitor is located proximate to the frontside of the second IC die.

Example 14 provides the IC package according to any of examples 1 to 11, where the first capacitor is located proximate to the frontside of the first IC die and the second capacitor is located proximate to the frontside of the second IC die.

Example 15 provides the IC package according to any of examples 1 to 11, where the first capacitor is located proximate to the backside of the first IC die and the second capacitor is located proximate to the backside of the second IC die.

Example 16 provides the IC package according to any of examples 1 to 15, where the logic circuit is situated in a FEOL portion of the first IC die (e.g., as shown in FIG. 1B).

Example 17 provides the IC package according to any of examples 1 to 16, where the first IC die is over a package substrate (e.g., 114), and the first IC die is electrically coupled to the package substrate with DTPS interconnects (e.g., 116).

Example 18 provides the IC package according to any of examples 1 to 17, where the first IC die further comprises a metal grid (e.g., as shown in FIG. 1C or 1D) having a first metal layer (e.g., 162 or 172) and a second metal layer (e.g., 164 or 174), where the first metal layer is above the first capacitor and the second metal layer is beneath the first capacitor. The metal grid is electrically coupled to the first capacitor with conductive vias (e.g., 166 or 176).

Example 19 provides the IC package according to example 18, where a spacing of the conductive vias is uniform (e.g., as shown in FIG. 1C).

Example 20 provides the IC package according to example 18, where a spacing of the conductive vias is non-uniform (e.g., as shown in FIG. 1D).

Example 21 provides the IC package according to any of examples 18 to 20, where a spacing of the conductive vias is based on a frequency response of the first capacitor or the second capacitor.

Example 22 provides the IC package according to any of examples 1 to 21, where the first capacitor and the second capacitor are selected based on a combined capacitance value of the first capacitor and the second capacitor.

Example 23 provides an IC die assembly having a first IC die (e.g., 102(1)) with a first capacitor (e.g., 108(1)) and a logic circuit (e.g., 104(1)), and a second IC die (e.g., 102(2)) with a second capacitor (e.g., 108(2)). The first IC die and the second IC die are electrically coupled to each other with die-to-die interconnects (e.g., 112), and the logic circuit is electrically coupled to the first capacitor and the second capacitor (e.g., as shown in FIG. 6A or 6B).

Example 24 provides the IC die assembly of example 23, where the first IC die further includes a first backside (e.g., 106(1)) and an opposing first frontside (e.g., 112(1)), the logic circuit is proximate to the first backside, the first capacitor is between the first backside and the first frontside, the second IC die further comprises a second backside (e.g., 106(2)) and an opposing second frontside (e.g., 110(2)), the second capacitor is between the second backside and the second frontside, and the DTD interconnects are over the first frontside and the second frontside.

Example 25 provides the IC die assembly of any of examples 23 to 24, where the first IC die is over the second IC die, the second die further includes DTPS interconnects (e.g., 116) on the first backside, TSVs (e.g., 124) in the second IC die electrically couple the DTPS interconnects with the second capacitor, and conductive traces (e.g., 146) in the first IC die electrically couple the DTD interconnects with the first capacitor.

Example 26 provides the IC die assembly of any of examples 23 to 25, where the first IC die is over the second IC die, and the first capacitor and the second capacitor are disposed at an input to the logic circuit (e.g., as shown in FIG. 5).

Example 27 provides the IC die assembly of examples 23 to 25, where the second IC die is over the first IC die, the first capacitor is at an input to the logic circuit, and the second capacitor is at an output from the logic circuit (e.g., FIG. 7).

Example 28 provides a PDN (e.g., as shown in FIGS. 3, 4, 5 and/or 7), including a DTPS interconnect, a first capacitor in a first IC die having a first logic circuit, a DTD interconnect, and a second capacitor in a second IC die having a second logic circuit. The DTPS interconnect is electrically coupled to the first capacitor. The first capacitor is electrically coupled to the DTD interconnect. The DTD interconnect is electrically coupled to the second capacitor.

Example 29 provides the PDN of example 28, where the first capacitor is electrically coupled an input of the first logic circuit, and the DTD interconnect is electrically coupled to an output of the first logic circuit (e.g., FIG. 3).

Example 30 provides the PDN of example 29, where the second capacitor is electrically coupled to an input of the second logic circuit (e.g., FIG. 3).

Example 31 provides the PDN of example 28, where the first capacitor is electrically coupled to an input of the second logic circuit (e.g., FIG. 5).

Example 32 provides the PDN of example 28, where the second capacitor is electrically coupled to an output of the second logic circuit (e.g., FIG. 7).

Example 33 provides the PDN of any of examples 28-32, where the DTPS interconnect is electrically coupled to the first capacitor by at least one TSV.

Example 34 provides the PDN of any of examples 28-33, where the PDN further includes a first metal grid electrically coupled between the at least one TSV and the first capacitor, a second metal grid electrically coupled between the first capacitor and an input to the first logic circuit, and a third metal grid electrically coupled between an output from the first logic circuit and the DTD interconnect (e.g., as shown in FIG. 3). The first metal grid comprises a power grid or a ground grid, and the second metal grid and the third metal grid comprise signal grids.

Example 35 provides the PDN of any of examples 28-34, where the PDN further includes a first metal grid electrically coupled between the DTPS interconnect and the first capacitor, a second metal grid electrically coupled between the first capacitor and the DTD interconnect, and a third metal grid electrically coupled between the second capacitor and the second logic circuit (e.g., as shown in FIG. 5). The first metal grid and the second metal grid comprise a power grid or a ground grid, and the third metal grid comprises a signal grid.

Example 36 provides the PDN of any of examples 28-35, in which electrical response of the PDN is programmable according to capacitance values and frequency response of the first capacitor and the second capacitor.

Example 37 provides the PDN of any of examples 28-36, in which the first IC die and the second IC die comprise any pair of IC dies in a plurality of stacked IC dies.

Example 38 provides a method for programming capacitance in a three-dimensional (3D) stacked die architecture. The method includes disposing a logic circuit and a first capacitor in a first IC die in an IC package, disposing a second capacitor in a second IC die in the IC package, and providing a PDN comprising electrically coupling the logic circuit in the PDN with the first capacitor and the second capacitor.

Example 39 provides a method of example 38, where the first capacitor is at an input to the logic circuit and the second capacitor is at an output from the logic circuit in the PDN.

Example 40 provides a method of example 38, where the first capacitor and the second capacitor are at an input to the logic circuit in the PDN.

Example 41 provides a method of any one of examples 38-40, further including disposing the second die on the first die and electrically coupling the second die to the first die with DTD interconnects.

Example 42 provides a method of any one of examples 38-41, further including disposing TSVs in the first IC die to electrically couple the DTD interconnects with the first capacitor through a metal grid.

Example 43 provides a method of any one of examples 38-42, further including combining PDNs in a PCB, a package substrate, the first die and the second die into one conductive pathway.

Example 44 provides a method of any of examples 38-43 where the first IC die and the second IC die are stacked one on top of another.

The above description of illustrated implementations of the disclosure, including what is described in the Abstract, is not intended to be exhaustive or to limit the disclosure to the precise forms disclosed. For example, although various embodiments have been described with reference to two dies, any number of dies in a stacked arrangement may be used within the scope of the present disclosure. While specific implementations of, and examples for, the disclosure are described herein for illustrative purposes, various equivalent modifications are possible within the scope of the disclosure, as those skilled in the relevant art will recognize.

1. An Integrated Circuit (IC) package, comprising:
a first IC die having a first capacitor and a logic circuit; and
a second IC die having a second capacitor, wherein:
the first IC die and the second IC die are stacked within the IC package, and
the logic circuit is electrically coupled to the first capacitor and the second capacitor.

2. The IC package of claim 1, wherein the first capacitor is coupled to an input to the logic circuit and the second capacitor is coupled to an output from the logic circuit.

3. The IC package of claim 1, wherein the first capacitor and the second capacitor are coupled to an input to the logic circuit.

4. The IC package of claim 3, wherein the first IC die is over the second IC die, wherein the second capacitor is situated in a shadow of the logic circuit.

5. The IC package of claim 1, wherein the first IC die and the second IC die comprise respective back-end-of-line (BEOL) portions, wherein the first capacitor and the second capacitor comprise metal-insulator-metal (MiM) capacitors in the respective BEOL portions.

6. The IC package of claim 1, wherein the second IC die is electrically coupled to the first IC die with die-to-die interconnects.

7. The IC package of claim 1, wherein the first IC die is over a package substrate, wherein the first IC die is electrically coupled to the package substrate with die-to-package-substrate (DTPS) interconnects.

8. The IC package of claim 1, wherein the first IC die further comprises a metal grid having a first metal layer and a second metal layer, wherein the first metal layer is above the first capacitor and the second metal layer is beneath the first capacitor, wherein the metal grid is electrically coupled to the first capacitor with conductive vias.

9. The IC package of claim 8, wherein a spacing of the conductive vias is uniform.

10. The IC package of claim 8, wherein a spacing of the conductive vias is non-uniform.

11. The IC package of claim 1, further comprising a through-substrate via (TSV) in the first IC die electrically coupled to the metal grid.

12. The IC package of claim 1, wherein the logic circuit is electrically coupled in a power delivery network (PDN) to the first capacitor and the second capacitor.

13. A power delivery network (PDN), comprising:
a die-to-package substrate (DTPS) interconnect;
a first capacitor in a first IC die having a first logic circuit;
a die-to-die (DTD) interconnect; and
a second capacitor in a second IC die having a second logic circuit, wherein:
the DTPS interconnect is electrically coupled to the first capacitor,
the first capacitor is electrically coupled to the DTD interconnect, and
the DTD interconnect is electrically coupled to the second capacitor.

14. The PDN of claim 13, wherein:
the first capacitor is electrically coupled to an input of the first logic circuit, and
the DTD interconnect is electrically coupled to an output of the first logic circuit.

15. The PDN of claim 13, wherein the first capacitor is electrically coupled to an input of the second logic circuit.

16. The PDN of claim 13, wherein the DTPS interconnect is electrically coupled to the first capacitor by at least one through-silicon via (TSV).

17. The PDN of claim 13, further comprising:
a first metal grid electrically coupled between the DTPS interconnect and the first capacitor;
a second metal grid electrically coupled between the first capacitor and an input to the first logic circuit; and
a third metal grid electrically coupled between an output from the first logic circuit and the DTD interconnect, wherein:
the first metal grid comprises a power grid or a ground grid, and
the second metal grid and the third metal grid comprise signal grids.

18. A system, comprising:
a first IC die having a first capacitor and a logic circuit;
a second IC die having a second capacitor;
a package substrate coupled to one of the first IC die and the second IC die; and
a printed circuit board (PCB) coupled to the package substrate, wherein:
the first IC die and the second IC die are stacked within the IC package over the package substrate, and
the logic circuit is electrically coupled to the first capacitor and the second capacitor.

19. The system of claim 18, wherein the first capacitor is at an input to the logic circuit and the second capacitor is at an output from the logic circuit.

20. The system of claim 18, wherein the first capacitor and the second capacitor are at an input to the logic circuit.
